(19) United States
(12) Patent Application Publication
(10) Pub. No.: US 2009/0050192 A1
(43) Pub. Date: Feb. 26, 2009

(54) Tracking-Type Photovoltaic Power Generation System, Method for Controlling the System, and Program Product for Controlling the System

(76) Inventors: Masao Tanaka, Osaka (JP); Osamu Anzawa, Nara (JP); Kosuke Ueda, Nara (JP); Takanori Nakano, Nara (JP)

Correspondence Address: NIXON & VANDERHYE, PC, 901 NORTH GLEBE ROAD, 11TH FLOOR, ARLINGTON, VA, 22203, US

(21) Appl. No.: 11/992,999

(22) PCT Filed: Sep. 26, 2006
(86) PCT No.: PCT/JP2006/319008

§ 371 Date: Nov. 4, 2008

(30) Foreign Application Priority Data
Oct. 5, 2005 (JP) 2005-292357

(51) Int. Cl. H01L 31/042

(52) U.S. Cl. 136/246

(57) ABSTRACT

There is provided a system control method which reduces maximum energy consumption in a tracking-type photovoltaic power generation system having a plurality of tracking-type photovoltaic power generation devices and reduces energy supply capacity. An integrated control part drives driving parts in each of tracking-type photovoltaic power generation devices at predetermined time intervals and drives the driving parts at different times, which can disperse temporally the large energy consumed at the time of activation of the driving parts in the tracking-type photovoltaic power generation devices, thereby reducing the energy supply capacity.

### TECHNICAL FIELD

The present invention relates to a tracking-type photovoltaic power generation system which always orients solar-cell module parts toward the sun to direct solar light to the solar cells for generating electric power, and a method for controlling the system. More specifically, the present invention relates to a tracking-type photovoltaic power generation system having a plurality of tracking-type photovoltaic power generation devices, a method for controlling the system, and a program product for controlling the system.

### BACKGROUND ART

In recent years, there has been a need for development of clean energy, in view of global environmental problems such as depletion of energy resources and increase of CO₂ in the air. Particularly, photovoltaic power generation using solar cells have been developed and put into practical use as a new energy source.

There has been a need for photovoltaic power generation systems with lower costs, in order to make them widely used. As one type of them, there has been developed a tracking-type photovoltaic power generation system which includes a driving part for tracking the solar light and sets solar-cell modules to the azimuth and altitude of the sun for increasing the power generation and reducing the power generation cost per unit amount of generated power. Further, there has been developed a light-gathering type tracking-type photovoltaic power generation system which tracks the sun and gathers the solar light for generating electric power, which can reduce the usage of solar cells which are the most expensive components in the photovoltaic power generation system, thereby reducing the cost of the entire system.

There have been some known sun tracking control methods for use in these systems, as described hereinafter.

Japanese Patent Laying-Open No. 2000-196126 (Patent Document 1) discloses a method which detects the direction of the sun using a sun-position sensor and tracks the sun, as a sun tracking control method for use in a tracking-type photovoltaic power generation system. Further, Japanese Patent Laying-Open No. 2002-202817 (Patent Document 2) discloses a method which calculates the azimuth and altitude of the sun on the basis of the latitude and longitude of the system installation position and the time and date, and then orients the light-receiving surfaces of solar-cell modules in that direction.

Further, there have been known similar methods for use in light-gathering type tracking type photovoltaic power generation systems. For example, Japanese Patent Laying-Open No. 2004-153202 (Patent Document 3) discloses a method which detects the direction of the sun from outputs of an optical sensor and orients the light-receiving surfaces of solar-cell modules to the azimuth and altitude of the sun. A light-gathering type system is similar in basic sun tracking operations to a tracking-type photovoltaic power generation system, but is different only in that its permissible tracking deviation angle is smaller thereby requiring higher accuracy of sun tracking, since it has a structure which gathers solar light with a lens and directs the solar light to the solar cells.

Conventionally, there have been made inventions of tracking-type photovoltaic power generation systems, such as inventions of methods for controlling a single tracking-type photovoltaic power generation device and the like, as disclosed in the aforementioned publications.

Patent Document 1: Japanese Patent Laying-Open No. 2000-196126

Patent Document 2: Japanese Patent Laying-Open No. 2002-202817

Patent Document 3: Japanese Patent Laying-Open No. 2004-153202

### DISCLOSURE OF THE INVENTION

### Problems to be Solved by the Invention

It is considered that tracking-type photovoltaic power generation systems can be advanced to equipment having a plurality of tracking-type photovoltaic power generation devices provided in a large site for generating large electric power. However, there have been hardly known a system structure for installing a plurality of tracking-type photovoltaic power generation devices and a method for controlling such a system.

In a case where only a single tracking-type photovoltaic power generation device is installed, energy supply equipment having energy capacity equal to or more than the maximum energy required for operating the device can be sufficient. On the other hand, in a case where a plurality of tracking-type photovoltaic power generation devices are installed and each of the devices is individually operated, each of the devices is operated at independent timings. Accordingly, depending on the situation, each of the devices can be activated at the same timing. As the scale of the system is increased, the probability that the devices are activated at the same timing is increased, thereby causing a problem that there arises a need for energy supply equipment having larger capacity corresponding to the number of tracking-type photovoltaic power generation devices.

The present invention was made in view of the aforementioned circumstances. It is an object of the present invention to provide a tracking-type photovoltaic power generation system capable of reducing energy supply capacity required for the tracking-type photovoltaic power generation system having a plurality of tracking-type photovoltaic power generation devices, a method for controlling the system, and a program product for controlling the system.

### Means to Solve the Problems

In order to achieve the aforementioned object, according to an aspect of the present invention, there is provided a tracking-type photovoltaic power generation system including a plurality of tracking-type photovoltaic power generation devices, each having a solar-cell module part and a driving part that changes the orientation of the solar-cell module part, and also including an integrated control part that controls the driving parts in the plurality of tracking-type photovoltaic power generation devices. The tracking-type photovoltaic power generation system is constituted by a plurality of units which are constituted by the tracking-type photovoltaic power generation devices. The driving parts in the tracking-type photovoltaic power generation devices are driven at predetermined time intervals, and the driving parts in the tracking-type photovoltaic power generation devices are activated at different times, on a unit-by-unit basis, to track the sun.

With this structure, it is possible to reduce the number of driving parts in tracking-type photovoltaic power generation devices which are subjected to activation operations at the same timing, thereby reducing the required energy supply capacity.

Preferably, the integrated control part includes a time keeping part that keeps time and date, a calculation part that calculates the azimuth and altitude of the sun, from the time and date and from the latitude and longitude of the position at which the tracking-type photovoltaic power generation devices are installed, and a control part that performs sun tracking control, on the basis of the calculated values of the azimuth and altitude of the sun.

Preferably, the driving parts further include rotation-angle detection parts that detect a rotation angle. The integrated control part obtains the direction in which the solar-cell module parts are oriented, on the basis of rotation-angle information detected by the rotation-angle detection parts, and drives the driving parts on the basis of the calculated values of the azimuth and altitude of the sun to track the sun.

Preferably, the tracking-type photovoltaic power generation devices further include receiving parts that receive, from the integrated control part, driving signals for setting the drive amount by which the driving parts should be driven, and distributed control parts having driving control parts that control the driving state of the driving parts.

Preferably, the predetermined time is set each time the driving parts are activated, such that the predetermined time is substantially inversely proportional to the calculated value of the sun movement angle per unit time at each activation time for the driving parts.

Preferably, sun tracking is performed, after the elapse of the predetermined time, such that the solar-cell module parts are oriented in the direction of the altitude and azimuth of the sun at the time advanced by ½ the predetermined time from the current time.

Preferably, the driving parts are activated and driven after sunset, such that the solar-cell module parts are oriented to the position at which the sun tracking is to be started in the next day. The driving parts are activated at different times. The number of driving parts which are activated at the same timing is equal to or less than the number of driving parts which are driven at the same timing during the sun tracking operation.

According to another aspect of the present invention, there is provided a method for controlling a tracking-type photovoltaic power generation system including a plurality of tracking-type photovoltaic power generation devices each having a solar-cell module part and a driving part that changes the orientation of the solar-cell module part, and also including an integrated control part that controls the driving parts in the plurality of tracking-type photovoltaic power generation devices. The tracking-type photovoltaic power generation system is constituted by a plurality of units which are constituted by a plurality of tracking-type photovoltaic power generation devices. The driving parts in the tracking-type photovoltaic power generation devices are activated and driven at predetermined time intervals, and the driving parts in the tracking-type photovoltaic power generation devices in the units are activated at different times on a unit-by-unit basis to track the sun.

By this control method, it is possible to reduce the number of driving parts in tracking-type photovoltaic power generation devices which are subjected to activation operations at the same timing, thereby reducing the required energy supply capacity.

According to still another aspect of the present invention, there is provided a program product that controls a tracking-type photovoltaic power generation system including a plurality of tracking-type photovoltaic power generation devices, each having a solar-cell module part and a driving part that changes the orientation of the solar-cell module part. The program product is adapted to execute the processes of transmitting driving signals for activating and driving the driving parts, at predetermined time intervals, to each of the tracking-type photovoltaic power generation devices. The program product causes the process of transmitting driving signals, at different times, to the plurality of units which are constituted by the plurality of tracking-type photovoltaic power generation devices and constitute the tracking-type photovoltaic power generation system.

By executing the control program, it is possible to reduce the number of driving parts in the tracking-type photovoltaic power generation devices which are subjected to activation operations at the same timing, thereby reducing the required energy supply capacity.

### Effects of the Invention

According to the present invention, when the tracking-type photovoltaic power generation system performs sun tracking operations, each of the tracking-type photovoltaic power generation devices is driven at predetermined time intervals, and also, the respective units constituted by one or more tracking-type photovoltaic power generation devices are activated at different times. This can reduce the number of tracking-type photovoltaic power generation devices which are activated at the same timing, thereby reducing the energy supply capacity required for the entire system.

### BRIEF DESCRIPTION OF THE DRAWINGS

FIG. 1 is a schematic view of a tracking light-gathering type photovoltaic power generation system according to an embodiment of the present invention.

FIG. 2 is a schematic view of a tracking light-gathering type photovoltaic power generation device according to the embodiment of the present invention.

FIG. 3 is a diagram illustrating the relationship between the sun movement angle per unit time and the time.

FIG. 4 is a timing chart of the operations of driving parts according to a first example of the present invention.

FIG. 5 is a flowchart of a control method according to the first example of the present invention.

FIG. 6 is a flowchart of a control program according to the first example of the present invention.

FIG. 7 is a flowchart of a control method according to a second example of the present invention.

FIG. 8 is a block diagram illustrating the hardware configuration of a computer system.

### DESCRIPTION OF THE REFERENCE SIGNS

1: tracking light-gathering type photovoltaic power generation device, 2: solar-cell module part, 3: driving part, 5: distributed control part, 6: orientation shaft, 7: inclination shaft, 8: power supply, 9: integrated control part, 10: integrated management room, 41a to 41e: units, 51: power-supply cable, 52: output electricity cable, 53: control cable, 55: receiving part, 61: rotation-angle detection part, 91: time measurement part, 92: calculation part, 93: control part, 800: computer system, 862: CD-ROM

### BEST MODES FOR CARRYING OUT THE INVENTION

Hereinafter, embodiments of the present invention will be described with reference to the drawings. In the following description, the same components are designated by the same reference signs. The same components also have the same names and functions. Therefore, the description thereof will not be repeated.

In the present embodiment, a tracking light-gathering type photovoltaic power generation system will be described as an exemplary tracking-type photovoltaic power generation system, but the present invention is not limited thereto. Even when the photovoltaic power generation system is not of a light-gathering type, it is possible to obtain similar effects. When the photovoltaic power generation system is not of a light-gathering type, the system is different only in that the permissible tracking deviation angle is larger, but the other parts can be deemed similar to those of a light-gathering type system.

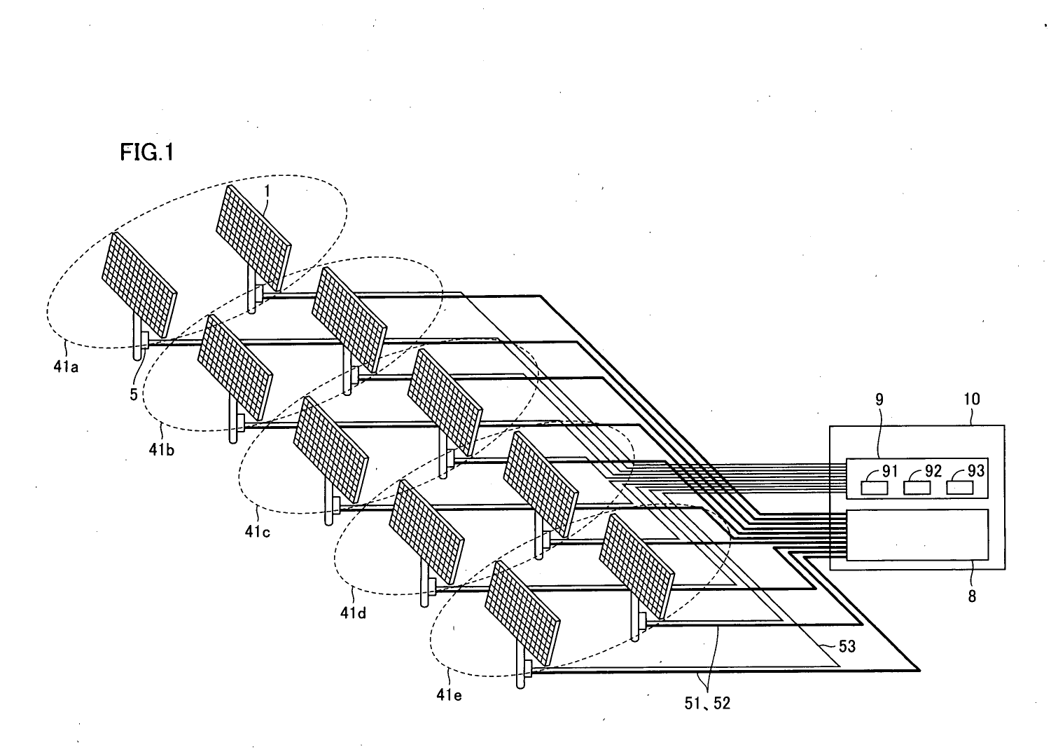

FIG. 1 is a schematic view of a tracking light-gathering type photovoltaic power generation system according to the present embodiment. The present tracking light-gathering type photovoltaic power generation system includes a plurality of tracking light-gathering type photovoltaic power generation devices 1 and an integrated control part 9 which collectively controls these devices. Integrated control part 9 is installed in an integrated management room 10.

Each tracking light-gathering type photovoltaic power generation device 1 is supplied with electric power from a power supply 8 provided in integrated management room 10 through power supply cables 51. Further, the electric power generated from each tracking light-gathering type photovoltaic power generation device 1 is collected in integrated management room 10 through output electricity cables 52.

Integrated control part 9 and tracking light-gathering type photovoltaic power generation devices 1 are interconnected through control cables 53. Each tracking light-gathering type photovoltaic power generation device 1 is controlled through communication via these cables. As the communication method, it is possible to employ any communication methods, e.g., serial communication and parallel communication, such as RS (Recommended Standard) 232C, RS485, USB (Universal Serial Bus), optical communication that are commonly used. Also, control signals can be superimposed in power supply cables 51 to use power supply cables 51 also as control cables.

Further, in wiring the cables actually, it is desirable to place power supply cables 51, output electricity cables 52, and control cables 53 such that they fall within the same wiring path in a state where they exert no influence on one another, in terms of the construction.

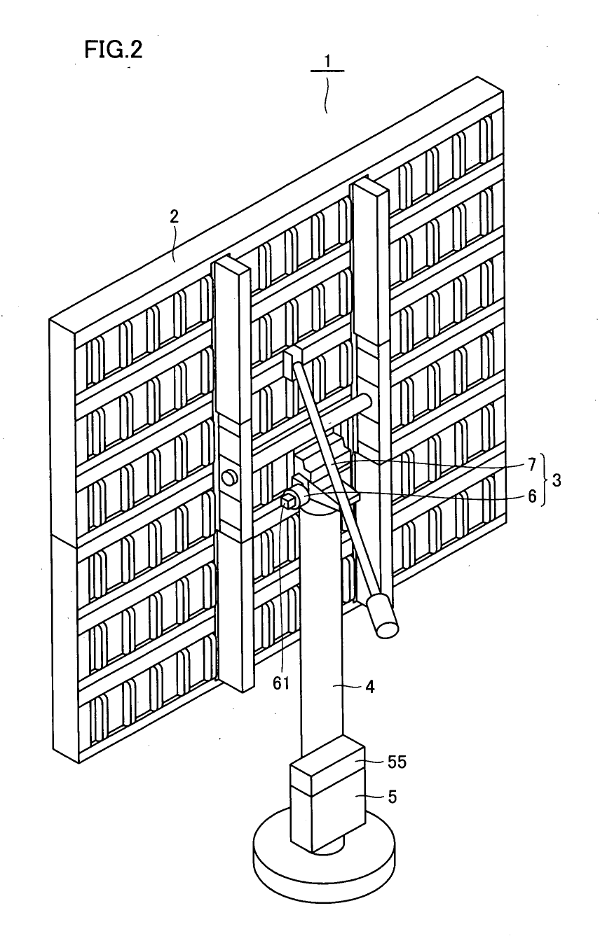

FIG. 2 illustrates a schematic view of tracking light-gathering type photovoltaic power generation device 1. A solar-cell module part 2 is driven by a driving part 3 in such a way as to track the sun. Driving part 3 is constituted by an orientation shaft 6 and an inclination shaft 7. Orientation shaft 6 and inclination shaft 7 are driven by electrically-driving devices, such as motors. A distributed control part 5 includes at least a motor driver for controlling the states of driving of the motors, and an I/F (interface) part for receiving driving signals from integrated control part 9.

Integrated control part 9 is connected to distributed control parts 5 in each tracking light-gathering type photovoltaic power generation device 1. The amount of rotation of each driving part 3 is set by driving signals transmitted from integrated control part 9. With this structure, each tracking type photovoltaic power generation device 1 can be directly connected to energy supply means, thereby simplifying the structure of the means.

The present system is constituted by a plurality of units 41a, 41b, 41c, 41d, and 41e, as illustrated in FIG. 1. Each unit is constituted by two tracking light-gathering type photovoltaic power generation devices 1. It is only necessary that each unit is constituted by one or more tracking light-gathering type photovoltaic power generation devices 1. In this case, integrated control part 9 controls each of tracking light-gathering type photovoltaic power generation devices 1, such that each tracking light-gathering type photovoltaic power generation device 1 is activated and driven at predetermined time intervals, and that driving parts 3 within the same unit are activated substantially at the same timing, while driving parts 3 in different units are activated at different times, on a unit-by-unit basis. More specifically, integrated control part 9 transmits driving signals to each of tracking light-gathering type photovoltaic power generation devices 1 at predetermined time intervals. Further, integrated control part 9 transmits driving signals to each of driving parts 3 in the same unit, substantially at the same timing. In this case, integrated control part 9 transmits such driving signals to each of the units at different times, on a unit-by-unit basis.

Driving parts 3 in the units are activated at different timings on a unit-by-unit basis, and therefore, driving parts 3 in tracking light-gathering type photovoltaic power generation devices 1 which are activated at the same timing are limited to driving parts in a single unit, at a maximum. With this structure and control method, it is possible to reduce the power-supply capacity required for driving parts 3 in tracking light-gathering type photovoltaic power generation devices 1.

In order to further reduce the power-supply capacity, it is desirable to make the numbers of respective tracking light-gathering type photovoltaic power generation devices 1 constituting the units equal to one another, and also to make the number of units to be a greatest possible number while making the number of tracking light-gathering type photovoltaic power generation devices 1 smaller. Further, in a case where each unit is constituted by a plurality of tracking light-gathering type photovoltaic power generation devices 1, it is more desirable to perform control in such a way as to stagger the activation timings for respective driving parts 3 in tracking light-gathering type photovoltaic power generation devices 1 within the same unit, from one another. In this case, it is possible to minimize the power-supply capacity.

In the present embodiment, control is performed in such a way that driving signals are transmitted to each of the units at different times, on a unit-by-unit basis, so that driving parts 3 are activated at different times. In this case, even if the time difference is small, it is possible to obtain the effect thereof The motors used in driving parts 3 generally have a characteristic that a large electric current referred to as a rush current flows therethrough at the time of activation thereof The peak value of this rush current determines the required power-supply capacity. That is, by staggering the activation timings for each of the units at which such a rush current flows, from one another, it is possible to obtain the power-supply-capacity reducing effect. The time period during which such a rush current flows is generally about several milliseconds, which is short. Therefore, by staggering the activation timings from one another by about 0.1 second, for example, it is possible to obtain the effect thereof.

As a method for further reducing the electric power consumption, there is possibly a method which determines preliminarily the time periods during which driving parts 3 in each tracking light-gathering type photovoltaic power generation device 1 are driven after their activation per predetermined period of time and drives driving parts 3 in each tracking light-gathering type photovoltaic power generation device 1 in such a way as to disperse the driving time periods as much as possible within the predetermined period of time. With this method, it is possible to reduce the number of tracking light-gathering type photovoltaic power generation devices 1 which are driven at the same timing, thereby reducing the required power-supply capacity.

Integrated control part 9 includes a time measurement part 91 for measuring time and date, a calculation part 92 for calculating the azimuth and altitude of the sun, on the basis of the time and date and the latitude and longitude of the position at which the present system is installed, and a control part 93 for performing sun tracking control on the basis of the azimuth and altitude of the sun. Integrated control part 9 transmits driving signals to distributed control parts 5 to cause them to control respective driving parts 3, such that solar-cell module parts 2 are oriented in the direction of the calculated azimuth and altitude. Integrated control part 9 is constituted by an electronic calculator.

With this structure, it is possible to integrate, into integrated control part 9, the calculation of the azimuth and altitude of the sun from the current time and the control of the driving parts for orientating the solar-cell module parts in the tracking type photovoltaic power generation devices in the direction of the calculated azimuth and altitude of the sun. As a result, the system can be simplified.

The latitude and longitude of the position at which the present system is installed may be preliminarily inputted to integrated control part 9 or may be automatically acquired through an installed GPS (Global Positioning System) receiving device. Further, in the case of installing such a GPS receiving device, it is possible to calibrate the time of integrated control part 9 by acquiring the time and date through the GPS receiving device.

As a method for detecting the direction in which solar-cell module parts 2 are oriented, there is a first method which mounts rotation-angle detection parts 61 such as sensors, potentiometers, rotary encoders, in driving parts 3, and determines the direction from rotation-angle information obtained from the rotation-angle detection parts. Also, there is a second method which integrates the amounts of movements caused by driving signals transmitted from when driving parts 3 existed at the original position to when driving parts 3 reached the current position. By the first method, it is possible to detect the actual rotation angle of the driving parts, which offers the advantage of enabling accurate determination of the direction in which the solar-cell module parts are oriented.

In the case of the first method, distributed control parts 5 are required to have a transmission part which receives rotation-angle information from driving parts 3 and transmits it to integrated control part 9, and also, integrated control part 9 is required to have a receiving part for receiving the information.

Integrated control part 9 makes a comparison between the current position determined through these methods and the value determined from the above calculation and transmits driving signals on the basis of the difference.

As described above, in the present embodiment, driving parts 3 in each tracking light-gathering type photovoltaic power generation device 1 are driven at predetermined time intervals for tracking the sun. Since driving parts 3 are operated at the predetermined time intervals, there is no need for continuously supplying electric power to the motors, thereby reducing the electric power for driving.

In the case where integrated control part 9 drives driving parts 3 at predetermined time intervals, the predetermined time is determined by the tracking angle deviation permitted by tracking light-gathering type photovoltaic power generation devices 1 and the operation time period required for a single operation of driving parts 3. That is, the predetermined time should be set to fall within the time period during which the outputs of solar-cell module parts 2 are not largely reduced during the stoppage of driving parts 3 and also should be set such that driving signals are not further transmitted during operation of driving parts 3. The permissible tracking angle deviation range is determined by the design of the optical systems in solar-cell module parts 2, and the time periods during which driving parts 3 are operated are determined by the designed rotation speed of driving parts 3.

Although the predetermined time is made to be a constant value determined on the basis of the time at which the sun movement angle is maximized, the predetermined time can also be set in such a way as to change the predetermined time at each time such that the predetermined time is substantially inversely proportional to the calculated value of the sun movement angle per unit time at each time. In the case of setting the predetermined time according to the latter method, it is possible to make the predetermined time to be longer during hour zones during which the sun movement angle is small while making the predetermined time to be shorter during hour zones during which the sun movement angle is large, which can offer the advantage of reducing the total number of times driving parts 3 are driven, thereby reducing the electric power for driving.

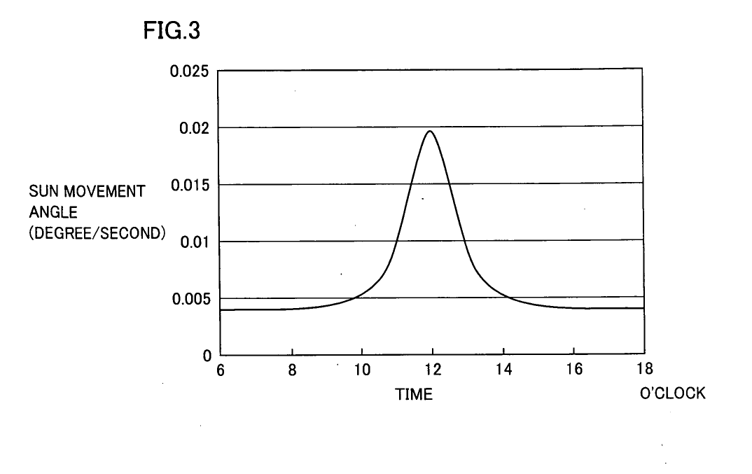

The sun movement angle at each time can be calculated from the position at which the tracking light-gathering type photovoltaic power generation system is installed and also from the time and date. FIG. 3 illustrates the relationship between the time of the day in which the sun movement angle per second is maximized (June, 22) and the calculated value of the sun movement angle per second, in Nara prefecture (at latitude 34.48 degrees north and longitude 135.73 degrees east) in Japan. As illustrated in FIG. 3, the sun movement angle per unit time is increased during an hour zone around midday.

In the present embodiment, it is desirable to control driving parts 3, after the elapse of the predetermined time, in such a way as to orient solar-cell module parts 2 in the direction of the altitude and azimuth of the sun at the time later by ½ the predetermined time from the current time. For example, assuming that the predetermined time is t₀, at a certain time t₁, driving parts 3 moves solar-cell module parts 2 to the position corresponding to the calculated values of the altitude and azimuth of the sun which are advanced by an amount corresponding to a time period of t₀/2 from the position corresponding to the altitude and azimuth of the sun at that time. At a time t₁+t₀, driving parts 3 also perform the same operation.

By the aforementioned control, solar-cell module parts 2 are caused to orient substantially in the direction of the sun at time t₀+t₀/2, so that the tracking deviation angle range caused by the stoppage during the predetermined time to falls within the sun movement angle for time periods of ±t₀/2. By this control, it is possible to further reduce the tracking deviation angle, thereby increasing power generation.

In the present embodiment, integrated control part 9 does not perform the aforementioned sun tracking operation after sunset. Integrated control part 9 drives driving parts 3 in tracking light-gathering type photovoltaic power generation devices 1, such that driving parts 3 are on standby at a tracking-operation starting position at the time of sunrise in the next day. In this case, integrated control part 9 detects sunset and sunrise in the following way, for example. That is, when the calculated value of the sun altitude is greater than 0 degree, integrated control part 9 detects sunrise, while when the calculated value of the sun altitude is equal to or less than 0 degree, integrated control part 9 detects sunset. Desirably, driving parts 3 are driven in such a way that the respective activation timings for driving parts 3 are staggered from one another as in the sun tracking operation, and it is only necessary that the maximum value of the electric-current consumption or the voltage does not exceed the capacity of power supply 8.

While, in the present embodiment, distributed control parts 5 are provided in each tracking light-gathering type photovoltaic power generation device 1, the functions of distributed control parts 5 can be partially or entirely integrated into integrated control part 9, and in this case, it is also possible to obtain similar effects as those described above.

In the present embodiment, the power source for the driving parts is electric motors. When the power source is of a hydraulically-driving type, large torque is required at the time of activation and the energy consumption is increased at the time of activation, and therefore, the effects of the control method according to the present embodiment can be offered as in the case of using motors.

Further, in order to construct a tracking light-gathering type photovoltaic power generation system on a larger scale, a plurality of tracking light-gathering type photovoltaic power generation systems described above can be provided, and a plurality of integrated control parts 9 can be controlled by another control part.

By the aforementioned system structure and control method, it is possible to simplify the system and reduce the required power supply capacity, thereby reducing the cost of the system.

### FIRST EXAMPLE

Hereinafter, a first example of the present invention will be described. The basic structure is similar to that of FIG. 1, and a tracking light-gathering type photovoltaic power generation system is constituted by 100 tracking light-gathering type photovoltaic power generation devices 1, wherein each two tracking light-gathering type photovoltaic power generation devices 1 form a single unit, and a total of fifty units are formed. Tracking light-gathering type photovoltaic power generation devices 1 in each unit are integrally controlled by an integrated control part 9.

Each tracking light-gathering type photovoltaic power generation device 1 is provided with an orientation shaft 6 and an inclination shaft 7 which are driven by AC (Alternate Current) induction motors, a distributed control part 5 which controls the driving of them, and a receiving part 55 which receives, from the integrated control part, driving signals for defining the drive amount by which a driving part should be driven. A rotary encoder and a potentiometer are provided on orientation shaft 6 and inclination shaft 7. Information about the rotation angles of the shafts is transmitted to integrated control part 9 through distributed control part 5. Distributed control part 5 includes a motor driver and a signal transmission/reception I/F and has the functions of transmitting rotation-angle information to integrated control part 9, receiving driving signals transmitted from integrated control part 9 through receiving part 55, and controlling the driving of the AC induction motors according to the signals.

Integrated control part 9 receives rotation-angle information of driving parts 3 from distributed control parts 5 in the units and, on the basis of the information, transmits driving signals to distributed control parts 5 for performing tracking control of tracking light-gathering type photovoltaic power generation devices 1.

More specifically, integrated control part 9 includes a time measurement part for measuring time and date, a calculation part for calculating the azimuth and altitude of the sun on the basis of the latitude and longitude of the position at which the present system is installed (for example, Nara prefecture (at latitude 34.48 degrees north and longitude 135.73 degrees east)) and on the basis of the time and date, and a position calculation part for calculating a current position of the direction in which each solar-cell module part 2 is oriented, from rotation-angle information of driving parts 3 in each tracking light-gathering type photovoltaic power generation device 1. Integrated control part 9 compares the calculated values of the azimuth and altitude of the sun with the current position and then transmits driving signals for activating driving parts 3 to each of tracking light-gathering type photovoltaic power generation devices 1, such that the calculated values fall within the permissible angle deviation range of solar-cell module parts 2. The sun tracking control is thus performed.

The acquisition of information about the latitude and longitude of the installation position of the present system and the calibration of time and date are performed on the basis of information acquired from a GPS receiving device installed in an integrated management room 10.

By the control method according to the present embodiment, integrated control part 9 transmits driving signals to distributed control parts 5 in each unit in turn, at 0.1-second intervals. Driving parts 3 in each tracking light-gathering type photovoltaic power generation device 1 are driven at predetermined time intervals, which are 6-seconds intervals, for tracking the sun.

When the AC induction motors used in the present example are activated, a rush current flows therethrough only for about 2 milliseconds after the activation of the motors. Accordingly, integrated control part 9 transmits driving signals to each distributed control part 5 for activating driving part 3 at 0.1-second intervals, which prevents rush currents from flowing through driving parts 3 at the same timing. It is only necessary that the interval between transmissions of driving signals is longer than the time period during which the rush current flows at the time of motor activation, and it is not limited to 0.1 second defined in the present example.

From calculation of the orbit of the sun at the position at which the system according to the present example is installed, it is found that the sun movement angle is maximized in June 22 within a single year of 2005. From the sun movement angle per second in Jun. 22, 2005 illustrated in FIG. 3, it can be seen that the maximum value of the sun movement angle is about 0.02 degree/second.

Present solar-cell module parts 2 include 180 sets of condenser lenses and solar cells. There are some errors among the sets. Therefore, it is inherently desirable to measure, actually, the permissible tracking deviation angles of tracking light-gathering type photovoltaic power generation devices 1 and set predetermined times as the intervals of the operations of driving part 3. In the present example, in order to ensure higher safety, the predetermined time is set such that the sun movement angle during stoppage is about ⅕ the permissible tracking deviation angle determined by the optical design.

More specifically, the permissible tracking deviation angle determined by the optical design of present tracking light-gathering type photovoltaic power generation devices 1 is about ±0.3 degree. If this range is exceeded, the generated electric power is reduced to 95% or less. Therefore, driving parts 3 in each tracking light-gathering type photovoltaic power generation device 1 are driven at predetermined time intervals, which are 6-seconds intervals.

In setting the predetermined time, integrated control part 9 may calculate the maximum value of the sun movement angle per unit time and, from the value, may calculate the predetermined time automatically.

By the aforementioned control method, it is possible to prevent driving parts 3 in tracking light-gathering type photovoltaic power generation devices 1 in different units from being activated at the same timing, which can cause rush currents to be flowed in a temporally-dispersed manner, at the time of activation of the motors. This can reduce the required power-supply capacity.

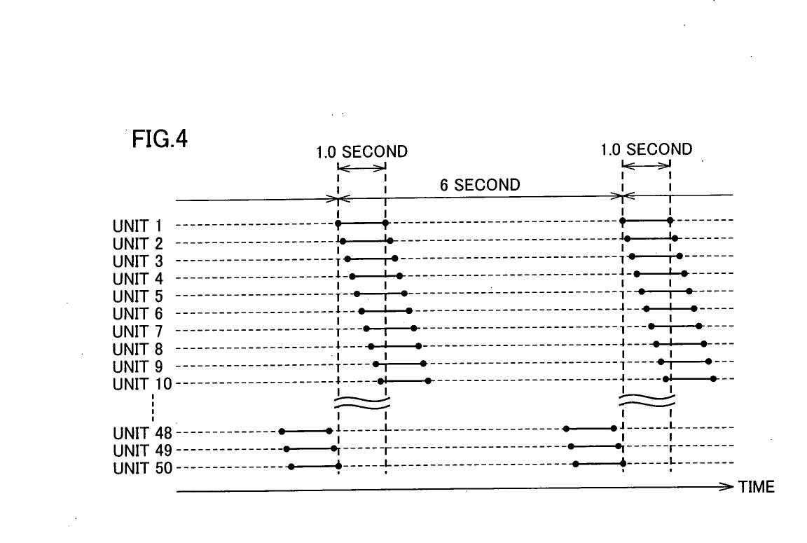

FIG. 4 illustrates a timing chart of operations of the driving parts during the sun tracking operation according to the present example. In FIG. 4, the abscissa axis represents time. The time intervals designated by solid lines indicate that each unit is being driven. The driving time period required to drive driving parts 3 a single time during tracking is determined by the rotation angle caused by a single drive and the rotation speed of the driving parts, and in the present example, the maximum value of the driving time period is smaller than 1 second. Therefore, the maximum number of units which are operated at the same timing is ten, and a single unit out of them is subjected to activation operation.

Each single unit is constituted by two tracking light-gathering type photovoltaic power generation devices 1, and the number of tracking light-gathering type photovoltaic power generation devices 1 which are operated at the same timing is twenty, and two tracking light-gathering type photovoltaic power generation devices 1 out of them are subjected to activation operation. In this case, the electric power consumption of each tracking light-gathering type photovoltaic power generation device 1 is 300 W (a voltage of 100 V and a maximum electric current of 3.0 A) at a maximum and is 96 W (a voltage of 100 V and an electric current of 0.96 A) during normal driving. In the case where the present control method is not employed, a maximum electric power of about 30 kW (a voltage of 100 V, an electric current of 300 A, and the electric power 300 W*100 devices) is required for driving tracking light-gathering type photovoltaic power generation devices 1. On the contrary, by employing the present control method, it is possible to reduce the maximum electric power during operation to about 2.328 kW (a voltage of 100 V and an electric current of 23.28 A) (96 W*18 devices+300 W*2 devices), thereby reducing the required power-supply capacity.

Further, the system according to the present example performs the following operations after sunset and before sunrise.

That is, when the value of the sun altitude calculated by integrated control part 9 becomes equal to or less than 0 degree during sun tracking operations, integrated control part 9 determines that the sun has set and stops the sun tracking operations. Thereafter, integrated control part 9 calculates the sunrise time at which the calculated value of the sun altitude becomes greater than 0 degree. Further, integrated control part 9 calculates the sun altitude and azimuth corresponding to the sunrise time in the next day (the tracking-operation starting position) and then drives driving parts 3 in tracking light-gathering type photovoltaic power generation devices 1 such that they are on standby at the position.

Regarding the method for controlling the system according to the present example, at first, the method for activating driving parts 3 is as follows. Integrated control part 9 activates and drives driving parts 3 at the same timing, on a unit-by-unit basis. After the driving of driving parts 3 in a single unit is stopped, integrated control part 9 drives driving parts 3 in another unit. Accordingly, driving parts 3 in each of the units are driven at different times. When the time becomes the calculated sunrise time, integrated control part 9 starts the aforementioned sun tracking operation and thereafter repeats these operations.

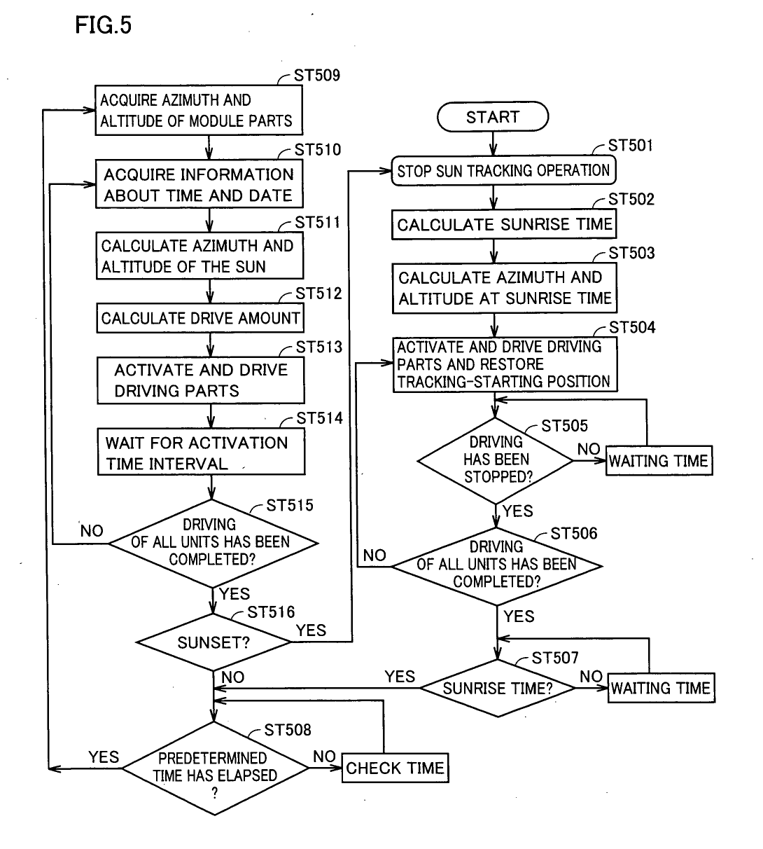

With reference to FIG. 5, a control method according to the present example will be described hereinafter. The present control is performed by integrated control part 9. FIG. 5 illustrates a flowchart of the control method according to the present example.

Integrated control part 9 stops the sun tracking operations of all tracking light-gathering type photovoltaic power generation devices 1 after sunset (step ST501), then calculates the sunrise time in the next day and stores it in an internal memory (not shown) (step ST502), and then calculates the azimuth and altitude of the sun at the sunrise time in the next day (the tracking-operation starting position) and stores it in the internal memory (step ST503).

Subsequently, integrated control part 9 activates and drives driving parts 3 in a single unit, out of the 50 units, to orient solar-cell module parts 2 therein to the tracking-operation starting position (step ST504). Integrated control part 9 ascertains whether the driving of this unit has been stopped (step ST505) and then activates and drives driving parts 3 in another unit to orient solar-cell module parts 2 therein to the tracking-operation starting position (step ST504). Hereinafter, integrated control part 9 repeats step ST504 and step ST505 and then ascertains whether the driving of all the units has been completed (step ST506).

Thereafter, when the current time is the sunrise time calculated in step ST502 (step ST507), integrated control part 9 ascertains whether a predetermined time (6 seconds) has elapsed (step ST508). Integrated control part 9 acquires the azimuth and altitude to which solar-cell module parts 2 in all tracking light-gathering type photovoltaic power generation devices 1 are oriented (step ST509), then obtains information about the time and date and the like (step ST510), and calculates the azimuth and altitude of the sun at the time (step ST511). Integrated control part 9 calculates the drive amount by which driving parts 3 should be driven, on the basis of the difference between the sun azimuth and altitude calculated in step ST511 and the values acquired in step ST509 (step ST512).

Integrated control part 9 drives driving parts 3 in a single unit, on the basis of the result of the calculation, to orient respective solar-cell module parts 2 to the sun azimuth and altitude calculated in step ST511 (step ST513). Integrated control part 9 repeats the aforementioned operations for driving parts 3 in tracking light-gathering type photovoltaic power generation devices 1 in all the units (step ST515), at 0.1-second intervals (activation time intervals) (step ST514), and ascertains whether the driving of driving parts 3 in tracking light-gathering type photovoltaic power generation devices 1 in all the units has been completed (step ST515).

Thereafter, integrated control part 9 ascertains whether or not the sun has set (step ST516). If the sun has not set (No in step S516), after the elapse of a predetermined time (6 seconds) since the previous predetermined time elapsed (step ST508), integrated control part 9 returns to step ST509. If the sun has set (Yes in step ST516), integrated control part 9 stops the sun tracking operations for all tracking light-gathering type photovoltaic power generation devices 1 (step ST501).

By repeating the aforementioned series of steps, integrated control part 9 can drive and control tracking light-gathering type photovoltaic power generation devices 1 in all the units. By this control method, it is possible to reduce the number of driving parts in tracking type photovoltaic power generation devices which are subjected to activation operation at the same timing, thereby reducing the required energy-supply capacity.

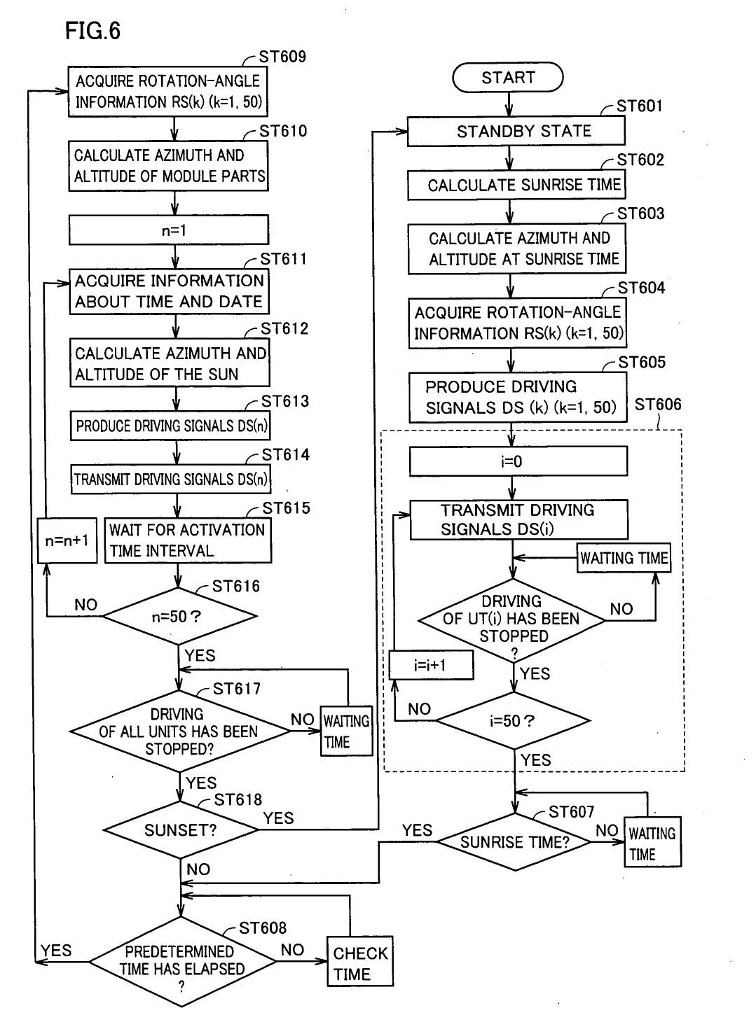

With reference to FIG. 6, the operations of a control program according to the present example will be described hereinafter. The present control program is executed by integrated control part 9.

FIG. 6 illustrates a flowchart of the control program according to the present example. Further, the units are expressed as units UT(1) to UT(50), driving signals for each unit are expressed as driving signals DS(1) to DS(50), and information indicative of the rotation angles of driving parts 3 are expressed as rotation-angle information RS(1) to RS(50).

Integrated control part 9 is brought into a standby state after sunset (step ST601), then calculates the sunrise time in the next day at which the altitude is larger than 0 degree, and stores it in the internal memory (step ST602). Further, integrated control part 9 calculates the azimuth and altitude of the sun at the sunrise time in the next day, then stores the azimuth and altitude of the sun in the memory (step ST603), and then obtains rotation-angle information RS(1) to RS(50) of driving parts 3 in units UT(1) to UT(50) (step ST604). Integrated control part 9 calculates the direction in which solar-cell module parts 2 in units UT(1) to UT(50) are oriented, on the basis of the rotation-angle information RS(1) to RS(50) of driving parts 3. Integrated control part 9 produces driving signals DS(1) to DS(50), from the difference from the sun azimuth and altitude at the sunrise time in the next day which were obtained in step ST603 (step ST605).

Thereafter, integrated control part 9 transmits driving signal DS(1) to unit UT(1). Integrated control part 9 orients solar-cell module parts 2 to the sun azimuth and altitude calculated in step ST603, then ascertains whether driving parts 3 in unit UT(1) have been stopped from the rotation-angle information RS(1), and thereafter transmits driving signals to unit UT(2). Integrated control part 9 repeats the aforementioned operations for all the units to set units UT(1) to UT(50) at the tracking starting position (step ST606). By the control, the driving parts which are activated at the same timing in tracking-starting-position restoring step ST504 are driving parts 3 included in tracking light-gathering type photovoltaic power generation devices 1 in a single unit.

Thereafter, when the current time is the sunrise time calculated in step ST602 (step ST607), integrated control part 9 ascertains whether a predetermined time (6 seconds) has elapsed since the sunrise time (step ST608), and obtains rotation-angle information RS(n) (n is an integer in the range of 1 to 50) (step ST609). Integrated control part 9 calculates the azimuth and altitude to which solar-cell module parts 2 in unit UT(n) are oriented, on the basis of rotation-angle information RS(n) (step ST610).

Further, integrated control part 9 obtains information about the time and date and the like (step ST611), then calculates the azimuth and altitude of the sun at the time (step ST612), and then produces driving signal DS(n) for activating driving parts 3, on the basis of the difference between the sun azimuth and altitude calculated in step ST610 and the azimuth and altitude calculated in step ST612 (step ST613). Integrated control part 9 transmits driving signal DS(n) to UT(n) (step ST614), and repeats steps ST611 to ST615 until the value of integer n is increased from 1 to 50 (step ST616), at 0.1-second intervals (activation time intervals) (step ST615). Integrated control part 9 ascertains whether the driving of driving parts 3 in units UT(1) to UT(50) has been stopped (step ST617), and then ascertains whether or not the sun has set, on the basis of the sun altitude calculated in step ST612 (step ST618). When the sun has not set, the control is returned to step ST609, after the elapse of a predetermined time (6 seconds) since the previous predetermined time elapsed (step ST608).

After the sun has set, integrated control part 9 stops the sun tracking operations of units UT(1) to UT(50) (step ST601). By repeating the aforementioned series of steps, integrated control part 9 can control and drive tracking light-gathering type photovoltaic power generation devices 1 in all the units. By executing the aforementioned program, integrated control part 9 can reduce the number of driving parts in the tracking type photovoltaic power generation devices which are subjected to activation operations at the same timing, thereby reducing the required energy supply capacity.

### SECOND EXAMPLE

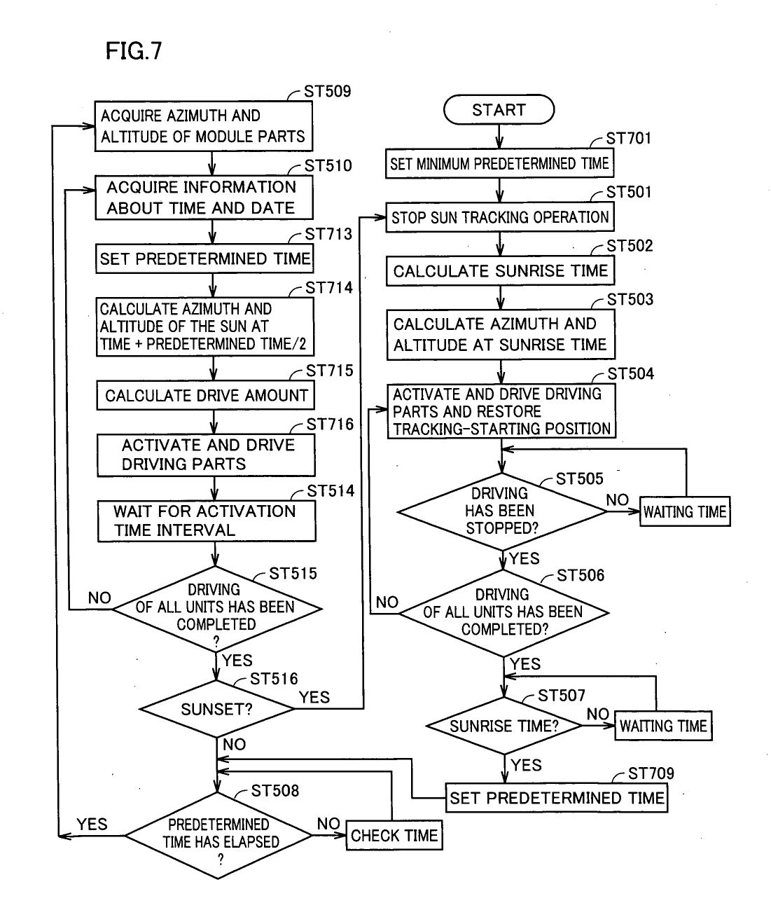

A second example of the present invention will be described hereinafter. The structure of the present example is similar to that of the first example, and only the controlling method thereof is partially different from the first example. Therefore, the present example will be described using a flowchart. FIG. 7 illustrates a flowchart of the control method according to the present example. This is similar to the flowchart of the first example (FIG. 5), but is different therefrom in the following respects.

At the time of activation of the system, integrated control part 9 calculates the maximum sun movement angle θm per unit time (1 second) within a single year, on the basis of the latitude and longitude acquired from the GPS receiving device installed in integrated management room 10, and sets a minimum predetermined time Tm such that the product of the maximum sun movement angle and the minimum predetermined time is ⅕ the designed value of permissible tracking deviation angle of solar-cell module parts 2 (step ST701).

On the basis of the calculated value θa of the sun movement angle at the sunrise time or each activation time, the minimum predetermined time Tm, and the maximum sun movement angle θm, integrated control part 9 calculates a predetermined time Ta as an activation time interval for driving parts 3 in each tracking light-gathering type photovoltaic power generation device 1, according to a calculation equation Ta=Tm*(θm/θa), and sets the predetermined time Ta in the internal memory (step ST709 and step ST713). Step ST709 is processing which is performed when the calculated value θa for the sunrise time is used in the aforementioned calculation equation. Step ST713 is for the case of each activation time of driving parts 3 in each tracking light-gathering type photovoltaic power generation device 1. In the present example, the minimum predetermined time Tm is 6 seconds and the maximum sun movement angle θm is 0.02 degree/second, and the predetermined time is set on the basis of these values.

Further, integrated control part 9 calculates the azimuth and altitude of the sun at the time advanced by ½ the predetermined time Ta from the current time (step ST714). Integrated control part 9 calculates the drive amount by which driving parts 3 should be driven, on the basis of these values (step ST715), and then drives driving parts 3 such that solar-cell module parts 2 are oriented in the direction of the sun azimuth and altitude (step ST716).

For example, for a certain tracking light-gathering type photovoltaic power generation device 1, integrated control part 9 activates and drives driving parts 3 at 10:30:30 a.m. In this case, when the predetermined time at this time is 10 seconds, integrated control part 9 performs control for orienting solar-cell module parts 2 in the direction of the calculated values of the azimuth and altitude of the sun at 10:30:35 a.m. by activating driving parts 3. By this control, the set values of the azimuth and altitude to which solar-cell module parts 2 are oriented are substantially coincident with the calculated values of the azimuth and altitude of the sun, at 10:30:35 a.m. The tracking angle deviation caused by the stoppage during the predetermined time of 10 seconds can be suppressed to the sun movement angle corresponding to a time period of about ±5 seconds. In the present control method, no consideration is taken for the time period during which driving parts 3 are driven, but it is also possible to grasp, preliminarily, the time period during which driving parts 3 are driven and perform control in consideration thereof, when the control is performed with higher accuracy. By this control method, it is possible to further reduce the tacking deviation angle, thereby increasing the power generation.

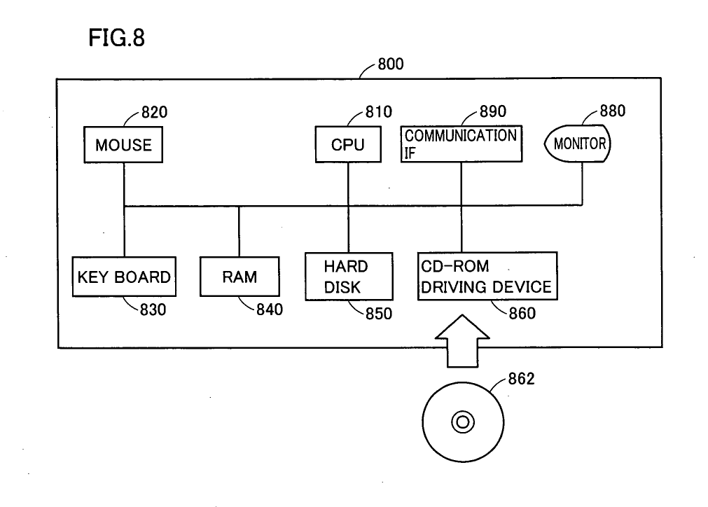

With reference to FIG. 8, there will be described an aspect of the detailed structure of integrated control part 9 according to the present embodiment. FIG. 8 is a block diagram illustrating the hardware configuration of a computer system 800 which functions as integrated control part 9.

Computer system 800 includes, as main components, a CPU 810 which executes programs, a mouse 820 and a key board 830 which receive instructions inputted by a user of computer system 800, a RAM 840 which stores, in a volatile manner, data generated by the execution of programs by CPU 810 or data inputted through mouse 820 or key board 830, a hard disk 850 which stores data in a non-volatile manner, a CD-ROM (Compact Disk-Read Only Memory) driving device 860, a monitor 880, and a communication IF (interface) 890. Each component of the hardware is interconnected through a data bus. A CD-ROM 862 is mounted to CD-ROM driving device 860.

Each component of the hardware and CPU 810 execute software which realizes processes in computer system 800. The software is preliminarily stored in hard disk 850 in some cases. Also, the software is stored in CD-ROMs 862 or other storage media which are distributed as program products, in some cases. Also, the software is provided as program products which can be downloaded, by so-called information providers connected to the Internet, in other cases. The software is read from such a storage medium by CD-ROM driving device 860 or another reading device or is downloaded through communication IF 890 and then is temporarily stored in hard disk 850. The software is read from hard disk 850 by CPU 810 and then is stored in RAM 840 in the form of executable programs. CPU 810 executes the programs. More specifically, CPU 810 executes a series of commands constituting the programs. The series of commands correspond to the respective steps included in the flowcharts of FIGS. 5 to 7.

The components constituting computer system 800 illustrated in FIG. 8 are common components. Accordingly, it can be said that the substantial part of the present invention is the software stored in RAM 840, hard disk 850, CD-ROM 862 or other storage media, or the software which can be downloaded through a network. It should be noted that the operations of each component of the hardware of computer system 800 are well known, and therefore, the detailed description will not be repeated.

Further, such recording media may be media which fixedly carry programs, such as magnetic tapes, cassette tapes, optical disks (MO (Magnetic Optical Disc)/MD (Mini Disc)/DVD (Digital Versatile Disc)), IC (Integrated Circuit) cards (including memory cards), optical cards, semiconductor memories such as mask ROMs, EPROMs (Electronically Programmable Read-Only Memory), EEPROMs (Electronically Erasable Programmable Read-Only Memory), Flash ROMs, as well as CD-ROMs, FDs (Flexible Disk), and hard disks.

The programs herein include programs in the form of source programs, compressed programs, encrypted programs, and the like, as well as programs which can be directly executed by CPUs.

The embodiments disclosed herein should be considered in all respects only as illustrative and not restrictive. The scope of the present invention is, therefore, defined by the appended claims and not by the foregoing description: All changes and modifications within the meaning and scope equivalent to the claims are intended to be encompassed within the scope of the present invention.

1. A tracking-type photovoltaic power generation system comprising:
a plurality of tracking-type photovoltaic power generation devices, each having a solar-cell module part and a driving part that changes orientation of said solar-cell module part; and
an integrated control part controlling said driving parts in said plurality of tracking-type photovoltaic power generation devices, wherein
said tracking-type photovoltaic power generation system is constituted by a plurality of units including said plurality of tracking-type photovoltaic power generation devices, and
each of said driving parts is driven at predetermined time intervals, and each of said driving parts is activated at different times on a unit-by-unit basis, to perform sun tracking.

2. The tracking-type photovoltaic power generation system according to claim 1, wherein
said integrated control part includes:
a time keeping part that keeping time and date;
a calculation part that calculating azimuth and altitude of the sun, from said time and date and from the latitude and longitude of a position at which said tracking-type photovoltaic power generation devices are installed; and
a control part performing sun tracking control, on the basis of the calculated values of said azimuth and altitude of the sun.

3. The tracking-type photovoltaic power generation system according to claim 2, wherein
said tracking-type photovoltaic power generation devices further include rotation-angle detection parts, connected to said driving parts, detecting their rotation angle, and
said integrated control part obtains a direction in which said solar-cell module parts are oriented, on the basis of rotation-angle information detected by said rotation-angle detection parts, and drives said driving parts on the basis of the calculated values of said azimuth and altitude of the sun to track the sun.

4. The tracking-type photovoltaic power generation system according to claim 1, wherein said tracking-type photovoltaic power generation devices further include receiving parts receiving driving signals for setting a drive amount by which said driving parts should be driven, from said integrated control part, and distributed control parts having driving control parts that control a driving state of said driving parts.

5. The tracking-type photovoltaic power generation system according to claim 1, wherein said predetermined time is set each time said driving parts are activated, such that said predetermined time is substantially inversely proportional to the calculated value of a sun movement angle per unit time at each activation time for said driving parts.

6. The tracking-type photovoltaic power generation system according to claim 1, wherein sun tracking is performed, after the elapse of said predetermined time, such that said solar-cell module parts are oriented to the direction of an altitude and an azimuth of the sun at a time advanced by ½ said predetermined time from a current time.

7. The tracking-type photovoltaic power generation system according to claim 1, wherein
said driving parts are activated and driven after sunset, such that said solar-cell module parts are oriented to a position at which the sun tracking is to be started in the next day, and said driving parts are driven at different times, and
the number of said driving parts which are driven at the same timing is equal to or less than the number of driving parts which are driven at the same timing during the sun tracking operation.

8. A method for controlling a tracking-type photovoltaic power generation system comprising a plurality of tracking-type photovoltaic power generation devices, each having a solar-cell module part and a driving part that changes orientation of said solar-cell module part, and an integrated control part that controls said driving parts in said plurality of tracking-type photovoltaic power generation devices,
said tracking-type photovoltaic power generation system being constituted by a plurality of units including said plurality of tracking-type photovoltaic power generation devices, the method comprising:
activating and driving said driving parts in said tracking-type photovoltaic power generation devices at predetermined time intervals; and
activating said driving parts in said tracking-type photovoltaic power generation devices in said units at different times on a unit-by-unit basis (ST513, ST514) to track the sun.

9. A program product that controls a tracking-type photovoltaic power generation system comprising a plurality of tracking-type photovoltaic power generation devices, each having a solar-cell module part and a driving part that changes orientation of said solar-cell module part, the program product being adapted to execute the processes of:
transmitting driving signals for activating and driving said driving parts, at predetermined time intervals, to each of said tracking-type photovoltaic power generation devices (ST613); and
transmitting said driving signals to said plurality of units including said plurality of tracking-type photovoltaic power generation devices and constituting said tracking-type photovoltaic power generation system, at different times.
